(19) United States
(12) Patent Application Publication
(10) Pub. No.: US 2005/0208726 A1
(43) Pub. Date: Sep. 22, 2005

(54) Spacer approach for CMOS devices

(76) Inventors: Sun-Jay Chang, Taitung County (TW); Shien-Yang Wu, Hsin-Chu (TW)

Correspondence Address: SLATER & MATSIL, L.L.P., 17950 PRESTON ROAD, SUITE 1000, DALLAS, TX, 75252, US

(21) Appl. No.: 10/804,397

(22) Filed: Mar. 19, 2004

(51) Int. Cl. H01L 21/336

(52) U.S. Cl. 438/303; 438/305; 438/306

(57) ABSTRACT

A semiconductor device having a graded source/drain region for use in CMOS devices is provided. The semiconductor device is formed by utilizing a spacer and a sacrificial spacer as masks. The sacrificial spacer is formed over an etch stop layer, which acts as an etch stop and protects underlying structures from becoming damaged during the etching process. In particular, the present invention may be used, for example, to protect the edge or corner of a shallow trench isolation from becoming damaged during etching.

### TECHNICAL FIELD

The present invention relates generally to semiconductor devices, and more particularly to a new spacer approach for use in fabricating complementary metal-oxide semiconductor (CMOS) devices.

### BACKGROUND

Complementary metal-oxide-semiconductor (CMOS) technology is the dominant semiconductor technology used for the manufacture of ultra-large scale integrated (ULSI) circuits today. Size reduction of the semiconductor structures has provided significant improvement in the speed, performance, circuit density, and cost per unit function of semiconductor chips over the past few decades. Significant challenges, however, are faced as the sizes of CMOS devices continue to decrease.

For example, as the length of the gate electrode of a CMOS transistor is reduced, the source and drain regions increasingly interact with the channel and gain influence on the channel potential and the gate dielectric. Consequently, a transistor with a short gate length suffers from problems related to the inability of the gate electrode to substantially control the on and off states of the channel. Phenomena such as reduced gate control associated with transistors with short channel lengths are termed short-channel effects.

One method of reducing the influence of the source and drain on the channel and the gate dielectric is to use graded junctions. Graded junctions are formed by performing multiple ion implants in the source and drain regions. Generally, the area of the source and drain regions adjacent to the gate electrode is lightly doped, and the area of the source and drain regions farther away from the gate electrodes is doped heavier.

One method of controlling the amount of doping includes forming sacrificial spacers comprising tetra-ethyl-ortho-silicate (TEOS) along the gate electrode. An ion implant is performed to dope the outer areas of the source and drain regions. The sacrificial spacers are removed and another ion implant is performed.

The use of sacrificial spacers formed of TEOS, however, frequently causes damage to other oxide structures, such as, for example, shallow trench isolations (STIs). Generally, STIs are trenches formed in the substrate and filled with an insulating material, usually a high-density plasma (HDP) oxide. When the sacrificial spacers formed of TEOS are removed, a portion or corner of the STI filler material may also be removed, which may adversely affect the electrical characteristics of the semiconductor devices, e.g., transistors, by increasing junction leakage at the edge of the STI.

### SUMMARY OF THE INVENTION

These and other problems are generally reduced, solved or circumvented, and technical advantages are generally achieved, by embodiments of the present invention, which provides a new spacer approach for fabricating CMOS devices.

In one embodiment of the present invention, a method of forming a semiconductor device is provided. This method includes providing a substrate having a gate electrode and spacers formed thereon. A first ion implant may be performed prior to forming the spacers to form lightly doped drains. A stop layer and sacrificial spacers are formed adjacent to the spacers and a second ion implant is performed. The sacrificial spacers are removed wherein the stop layer prevents the STIs, particularly the edges, from becoming damaged. A third ion implant may then be performed.

In another embodiment of the present invention, another method of forming a semiconductor device is provided. This method includes providing a substrate having a gate electrode and spacers formed thereon. A first ion implant may be performed prior to forming the spacers to form lightly doped drains. A second ion implant is performed and sacrificial spacers are formed adjacent to the spacers. A third ion implant is performed, and the sacrificial spacers may be removed.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1-5 are cross-section views of a wafer after performing various process steps in accordance with an embodiment of the present invention in which an etch stop layer is formed below a sacrificial layer; and

FIGS. 6-11 are cross-section views of a wafer after performing various process steps in accordance with another embodiment of the present invention in which an etch stop layer is formed below a sacrificial layer.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. Accordingly, the specific embodiments discussed herein are merely illustrative of specific ways to make and use the invention, and do not limit the scope of the invention.

The invention described herein provides a method for forming a transistor characterized by good short channel control and avoiding damage to STIs or other structures. In particular, the method of the present invention described herein provides a method of forming graded source/drain regions to provide better short channel control using sacrificial spacers and etch stop layers. As will be discussed below, an etch stop layer is formed before the sacrificial spacers are formed and covers the STIs or other underlying structures. Materials used for the etch stop layer and the sacrificial spacers are such that a high etch selectivity exists between the two materials. In this manner, the etch stop layer allows the sacrificial spacers to be formed and stripped without causing damage to the STIs or other underlying structures. One of the advantages of methods of the present invention is the ability to reduce damage to the edges of the STIs, thereby reducing the junction leakage at the edges of the STIs.

Embodiments of the present invention are illustrated in the context of fabricating a transistor, namely an NMOS transistor, for illustrative purposes only. The techniques described herein may be used to fabricate other devices, including a PMOS transistor.

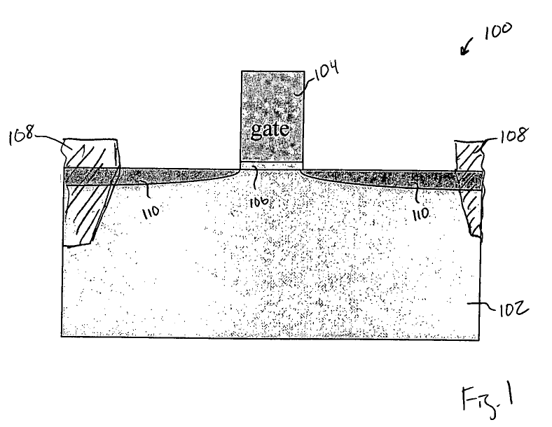

FIGS. 1-5 illustrate cross-section views of a portion of a semiconductor wafer 100 during various steps of an embodiment of the present invention. The process begins in FIG. 1, wherein a semiconductor wafer 100 having a substrate 102 with a gate electrode 104 and a gate dielectric 106 formed thereon by processes known in the art is provided. Furthermore, STIs 108 are formed in the substrate 102 to isolate the active areas from other active areas that may be contained on the substrate. The STIs 108 are generally filled with a dielectric material such as a high-density plasma oxide.

A first ion implant region 110 is preferably an n-type lightly doped drain (NLDD) defining the source/drain regions. The first ion implant regions 110 may be doped with, for example, an N− dopant, such as arsenic ions at a dose of about 1E14 to about 5E14 atoms/cm² and at an energy of about 1 to about 3 KeV. Alternatively, the first ion implant regions 110 may be doped with other n-type dopants such as nitrogen, phosphorous, antimony, or the like. P-type dopants, such as boron, aluminum, gallium, indium, and the like, may be used to fabricate PMOS devices.

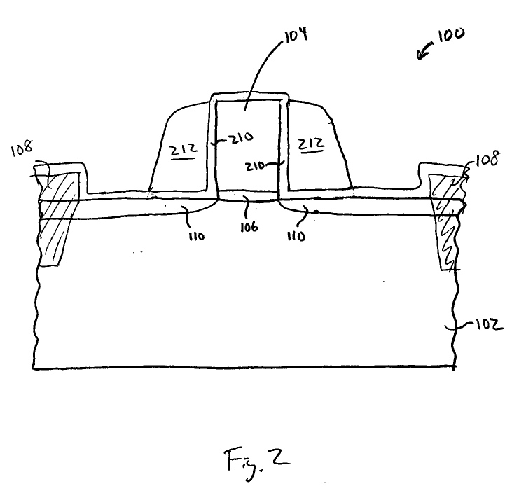

FIG. 2 illustrates the wafer 100 of FIG. 1 after an etch stop layer 210 and a spacer 212 have been formed thereon. Preferably, the etch stop layer 210, which acts as an etch stop when etching the spacer 212, is an oxide formed by any oxidation process, such as wet or dry thermal oxidation in an ambient comprising an oxide, H₂O, NO, or a combination thereof, or by chemical vapor deposition (CVD) techniques using tetra-ethyl-ortho-silicate (TEOS) and oxygen as a precursor. In the preferred embodiment, the etch stop layer 210 is about 20 Å to about 200 Å in thickness, but more preferably about 100 Å in thickness.

The spacer 212, which forms a spacer for an ion implant performed in a later step, preferably comprises silicon nitride (Si₃N₄), or another nitrogen-containing layer, such as SiₓN_{y}, silicon oxynitride SiOₓN_{y}, silicon oxime SiOₓN_{y}:H_{z}, or a combination thereof. In a preferred embodiment, the spacer 212 is formed from a layer comprising Si₃N₄ that has been formed using CVD techniques using silane and ammonia as precursor gases, and deposition temperatures ranging from 450° to 650° C. to a thickness of about 400 Å to about 1000 Å, but more preferably about 500 Å. Other films that can be deposited substantially uniform on the wafer 100 may also be used.

The spacer 212 may be patterned by performing an anisotropic dry etch process wherein the etch stop layer 210 acts as an etch stop. It should be noted that SiO₂ and Si₃N₄ are preferred for the etch stop layer 210 and the spacer 212, respectively, because of the high etch selectivity between these materials. Because of the high etch selectivity, the SiO₂ protects underlying structures, e.g., STIs 108, from becoming damaged during the dry etch process to form the spacers 212. As discussed above, preventing damage to the STIs 108 is desirable because it helps reduce the junction leakage at the corners of the STIs 108. Other materials may be used provided that a high etch selectivity exists between the materials.

In the preferred embodiment, the etch stop layer 210 is not removed unless it adversely affects subsequent processing steps. In the embodiment discussed herein in which a transistor is being formed, the etch stop layer 210 does not adversely affect the formation of the transistor. Furthermore, by leaving the etch stop layer 210 in place, there is no risk of damaging structures beneath the etch stop layer 210, such as the STIs 108. Not removing the etch stop layer 210 also saves the need for an additional process step.

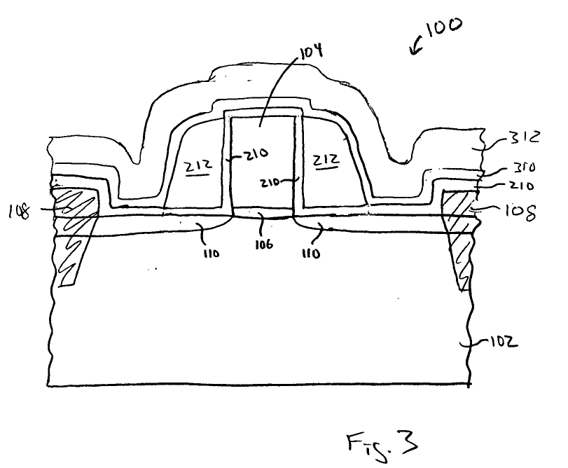

FIG. 3 illustrates the wafer 100 of FIG. 2 after a second etch stop layer 310 and a sacrificial (or dummy) spacer layer 312 have been formed thereon. The second etch stop layer 310 acts as an etch stop during the etching process of sacrificial spacer layer 312.

The second etch stop layer 310 is preferably an oxide layer formed, for example, by chemical vapor deposition (CVD) techniques using tetra-ethyl-ortho-silicate (TEOS) and oxygen as a precursor. In the preferred embodiment, the second etch stop layer 310 is about 20 Å to about 100 Å in thickness, but more preferably about 60 Å in thickness.

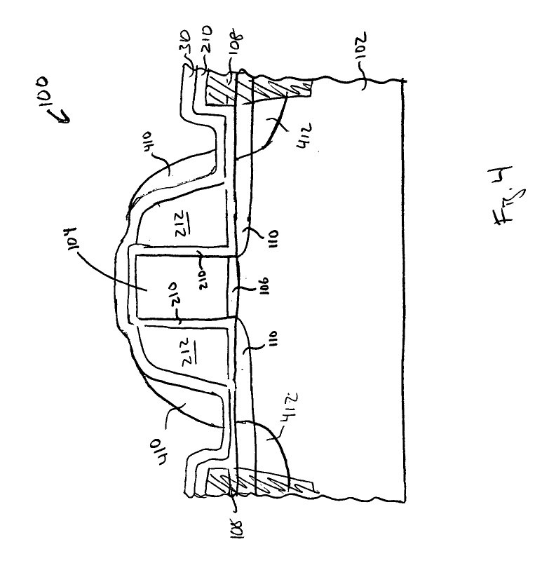

The sacrificial spacer layer 312, which forms a spacer for an ion implant performed in a later step (see sacrificial spacer 410 of FIG. 4), preferably comprises Si₃N₄, or another nitrogen-containing layer, such as SiₓN_{y}, silicon oxynitride SiOₓN_{y}, silicon oxime SiOₓN_{y}:H₂, or a combination thereof. In a preferred embodiment, the sacrificial spacer layer 312 is formed from a layer comprising Si₃N₄ that has been formed using CVD techniques using silane and ammonia as precursor gases, and deposition temperatures ranging from about 400° to about 600° C. to a thickness of about 200 Å to about 500 Å, but more preferably about 300 Å.

FIG. 4 illustrates the wafer 100 of FIG. 3 after sacrificial spacers 410 have been formed thereon and a second ion implant has been performed. After forming the sacrificial spacer layer 312 (FIG. 3), the sacrificial spacers 410 may be patterned by dry etching.

It should be noted that the material for the second etch stop layer 310 is selected such that there is a high etch selectivity between the Si₃N₄ used to form the sacrificial spacers 410 and the second etch stop layer 310. The high etch selectivity allows the sacrificial spacers 410 to be formed, and removed, without damaging the structures below the second etch stop layer 310, such as the STIs 108.

After forming the sacrificial spacers 410, a second ion implant region 412 is formed. Preferably, the second ion implant region 412 is formed, for example, using an N+ dopant, such as, for example, arsenic ions at a dose of about 5E14 to about 5E15 atoms/cm² and at an energy of about 3 to about 10 KeV. Alternatively, other n-type dopants, such as nitrogen, phosphorous, antimony, or the like, may be used. P-type dopants, such as, boron, aluminum, gallium, indium, and the like, may be used to fabricate PMOS devices.

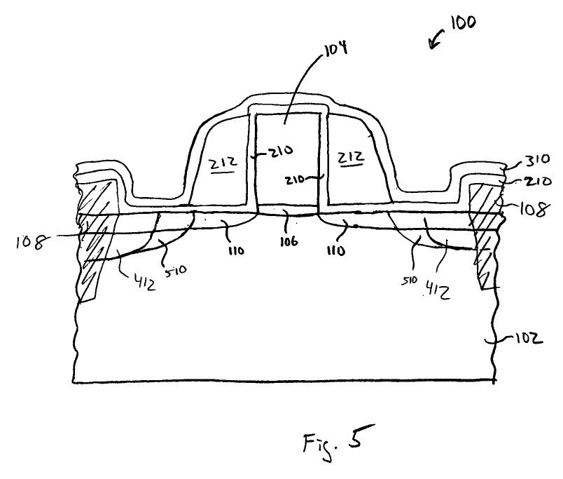

FIG. 5 illustrates the wafer 100 of FIG. 4 after the sacrificial spacers 410 (FIG. 4) have been removed and a third ion implant region 510 has been formed. The sacrificial spacers 410 may be removed by performing a wet etching in a solution of phosphoric acid (H₃PO₄). It has been found that phosphoric acid has a high etch selectivity between the Si₃N₄ of the sacrificial spacers 410 and the CVD oxide of the second etch stop layer 310, thereby allowing the sacrificial spacers 410 to be removed without causing damage to the spacers 212 or the STIs 108. The removal of the sacrificial spacers 410, however, may cause the second etch stop layer 310 to be partially or entirely removed.

The third ion implant region 510 may be formed, for example, using an N− dopant, such as, for example, arsenic ions at a dose of about 1E14 to about 5E15 atoms/cm² and at an energy of about 3 to about 10 KeV. Alternatively, other n-type dopants, such as nitrogen, phosphorous, antimony, or the like, may be used. P-type dopants, such as, boron, aluminum, gallium, indium, and the like, may be used to fabricate PMOS devices.

Thereafter, standard processing techniques may be used to complete fabrication of the semiconductor device. For example, contact areas may be silicided, source polysilicon plugs, word lines, and bit lines may be formed, and the like.

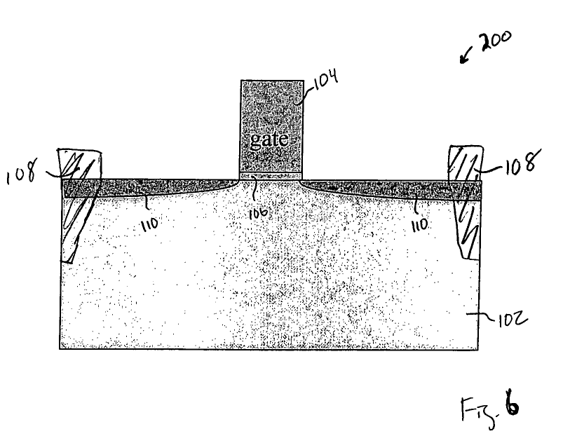

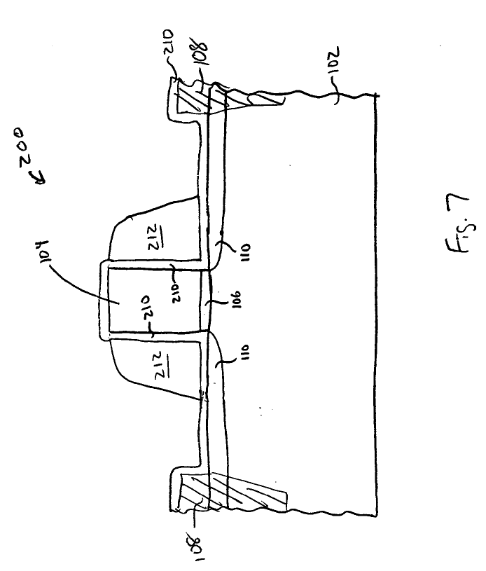

FIGS. 6-10 are cross-section views of an alternative embodiment in which the order of the second and third ion implants are reversed, i.e., the third ion implant may be performed prior to forming the sacrificial spacers 410 (FIG. 4). Accordingly, FIGS. 6 and 7 illustrate a wafer 200, wherein the wafer 200 may be provided, for example, as described above with reference to FIGS. 1 and 2, respectively, wherein like reference numerals refer to like elements.

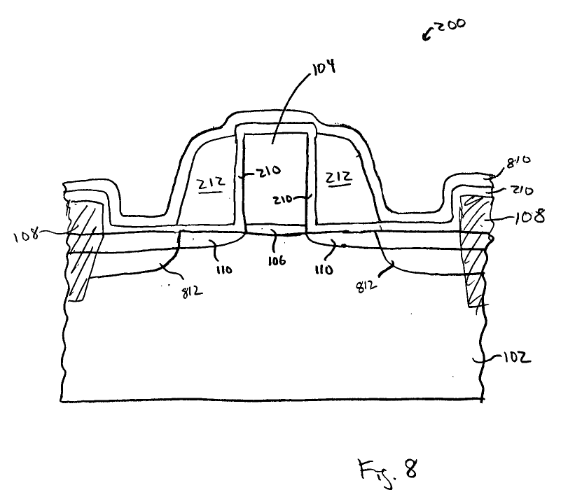

FIG. 8 illustrates the wafer 200 of FIG. 7 after an etch stop layer 810 is formed and a second ion implant region 812 is formed. The second ion implant region 812 may be formed, for example, using an N− dopant, such as, for example, arsenic ions at a dose of about 1E14 to about 5E14 atoms/cm² and at an energy of about 1 to about 3 KeV. Alternatively, other n-type dopants, such as nitrogen, phosphorous, antimony, or the like, may be used. P-type dopants, such as, boron, aluminum, gallium, indium, and the like, may be used to fabricate PMOS devices.

The etch stop layer 810 may be formed, for example, as disclosed above in reference to the second etch stop layer 310 (FIG. 3) of the first embodiment. Additionally, the etch stop layer 810 may alternatively be formed prior to or after the second ion implant region 812 is formed.

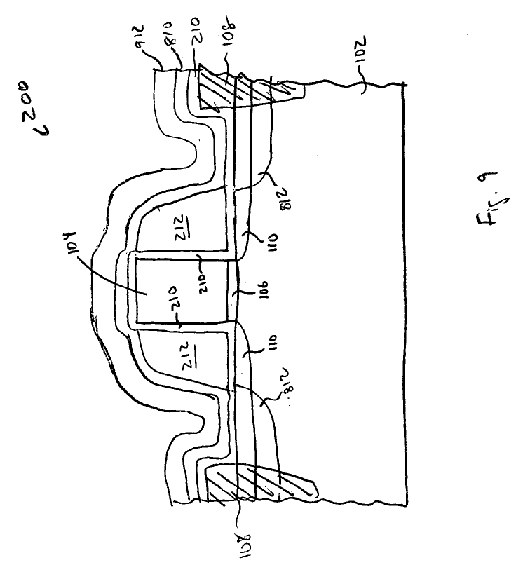

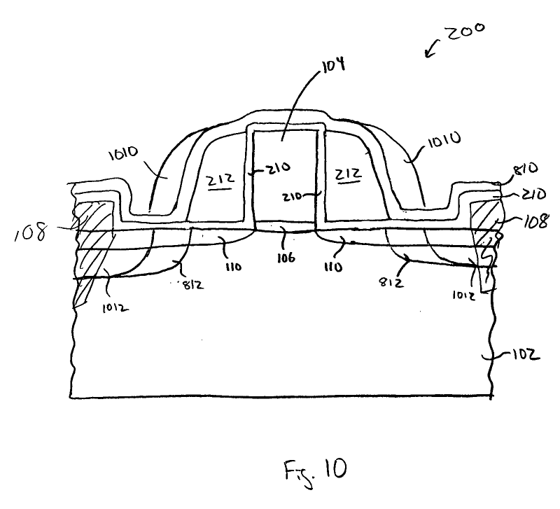

FIG. 9 illustrates the wafer 200 of FIG. 8 after a sacrificial (or dummy) spacer layer 912 has been formed thereon. The sacrificial spacer layer 912 may be formed, for example, as described above with reference to the sacrificial spacer layer 312 (FIG. 3). In FIG. 10, the sacrificial spacer layer 912 (FIG. 9) has been patterned to form sacrificial spacers 1010, preferably as disclosed above with reference to sacrificial spacers 410 (FIG. 4).

After forming the sacrificial spacers 1010, a third ion implant region 1012 is formed. Preferably, the third ion implant region 1012 may be formed, for example, using an N+ dopant, such as, for example, arsenic ions at a dose of about 5E14 to about 5E15 atoms/cm² and at an energy of about 3 to about 10 KeV. Alternatively, other n-type dopants, such as nitrogen, phosphorous, antimony, or the like, may be used. P-type dopants, such as, boron, aluminum, gallium, indium, and the like, may be used to fabricate PMOS devices.

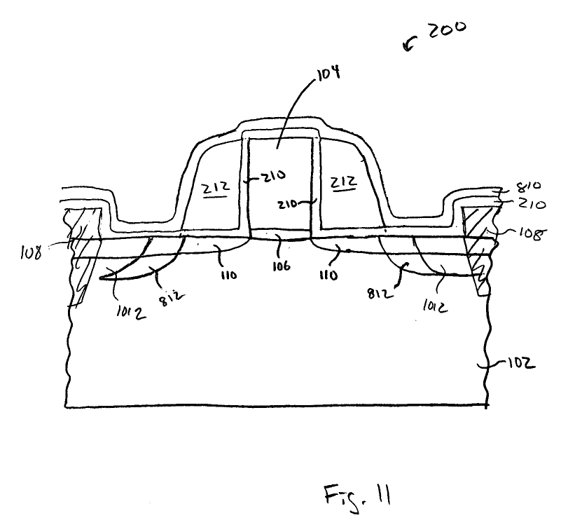

FIG. 11 illustrates wafer 200 of FIG. 10 after the sacrificial spacers 1010 (FIG. 10) have been removed, wherein the etch stop layer 810 prevents the STIs and other underlying structures from becoming damaged. The sacrificial spacers 1010 may be removed, for example, as described above with reference to the removal of sacrificial spacers 410 of FIG. 4.

Although particular embodiments of the invention have been described in detail with reference to specific embodiments, it is understood that the invention is not limited-correspondingly in scope, but includes all changes, modifications, and equivalents coming within the spirit and terms of the claims appended hereto. For example, differing types of materials and differing thicknesses may be used, other NMOS or PMOS devices may be fabricated, and the like. Furthermore, materials used for the spacers and etch stop layers may be switched. For example, the spacers may be formed of an oxide, such as TEOS, and the etch stop layers may be formed of silicon nitride. Other types of materials may be used that exhibit high etch selectivity between the material used for the spacers and the material used for the etch stop layers.

Accordingly, it is understood that this invention may be extended to other structures and materials, and thus, the specification and figures are to be regarded in an illustrative rather than a restrictive sense.

1. A method of forming a semiconductor device, the method comprising:
providing a substrate having a gate electrode formed thereon;
performing a first ion implant wherein the gate electrode acts as a mask;
forming a first spacer on the substrate adjacent to the gate electrode;
forming an etch stop layer on the substrate;
forming a sacrificial spacer on the second etch stop layer on the substrate adjacent to the first spacer;
performing a second ion implant wherein the sacrificial spacer and the first spacer acts as a mask;
removing the sacrificial spacer; and
performing a third ion implant wherein the first spacer acts as a mask.

2. The method of claim 1, wherein the step of forming the first spacer includes forming a dielectric liner on the substrate, forming a first spacer layer, and etching the first spacer layer wherein the dielectric liner acts as an etch stop.

3. The method of claim 2, wherein exposed portions of the dielectric liner are removed after forming the first spacer.

4. The method of claim 1, wherein the etch stop layer covers a shallow trench isolation.

5. The method of claim 1, wherein the third ion implant is performed before the second ion implant.

6. The method of claim 1, wherein the first spacer comprises a material selected from the group consisting of silicon nitride, silicon oxynitride, silicon oxime, a nitrogen containing material, and a combination thereof.

7. The method of claim 1, wherein the etch stop layer is an oxide.

8. The method of claim 1, wherein the sacrificial spacer comprises a material selected from the group consisting of silicon nitride, silicon oxynitride, silicon oxime, a nitrogen containing material, and a combination thereof.

9. The method of claim 1, wherein the step of forming the sacrificial spacer includes depositing a layer of Si3N4 and performing an anisotrophic dry etch.

10. The method of claim 1, wherein the etch stop layer is an oxide formed by chemical vapor deposition techniques.

11. The method of claim 1, wherein the step of removing the sacrificial layer is performed by an etch process using a solution of phosphoric acid.

12. A method of forming a semiconductor device, the method comprising:
providing a substrate having a gate electrode and a shallow trench isolation (STI) formed thereon;
forming a lightly doped drain in the substrate adjacent to the gate electrode;
forming a first spacer on the substrate adjacent to the gate electrode;
forming an etch stop layer on the substrate and over the STI;
forming a sacrificial spacer on the etch stop layer adjacent to the first spacer, the etch stop layer preventing damage to the STI;
performing a second ion implant wherein the first spacer and the sacrificial spacer act as a mask;
removing the sacrificial spacer, the etch stop layer preventing damage to the STI; and
performing a third ion implant wherein the first spacer acts as a mask.

13. The method of claim 12, wherein the step of forming the first spacer includes forming a dielectric liner on the substrate, forming a first spacer layer, and etching the first spacer layer wherein the dielectric liner acts as an etch stop.

14. The method of claim 13, wherein exposed portions of the dielectric liner are removed after forming the first spacer.

15. The method of claim 12, wherein the third ion implant is performed before the second ion implant.

16. The method of claim 12, wherein the step of forming the sacrificial spacer includes forming a sacrificial layer and patterning the sacrificial layer to form the sacrificial spacer by performing an anisotrophic dry etch.

17. The method of claim 16, wherein the step of removing the sacrificial spacer is performed using a solution of phosphoric acid.

18. The method of claim 12, wherein the sacrificial spacer comprises a material selected from the group consisting of silicon nitride, silicon oxynitride, silicon oxime, a nitrogen containing material, and a combination thereof.

19. The method of claim 12, wherein the second etch stop layer is an oxide.

20. The method of claim 19, wherein the oxide is formed by chemical vapor deposition techniques.
